(19) United States
(12) Patent Application Publication
(10) Pub. No.: US 2025/0351350 A1
(43) Pub. Date: Nov. 13, 2025

(54) SEMICONDUCTOR MEMORY DEVICE

(71) Applicant: SK hynix Inc., Icheon-si Gyeonggi-do (KR)

(72) Inventor: Heon Yong CHANG, Icheon-si Gyeonggi-do (KR)

(73) Assignee: SK hynix Inc., Icheon-si Gyeonggi-do (KR)

(21) Appl. No.: 18/908,352

(22) Filed: Oct. 7, 2024

(30) Foreign Application Priority Data
May 7, 2024 (KR) 10-2024-0059819

(51) Int. Cl. H10B 43/27; H01L 23/00; H01L 25/00; H01L 25/065; H01L 25/18; H10B 41/27; H10B 41/35; H10B 43/35; H10B 80/00

(52) U.S. Cl. CPC H10B 43/27; H01L 24/08; H01L 24/80; H01L 25/0657; H01L 25/18; H01L 25/50; H10B 41/27; H10B 41/35; H10B 43/35; H10B 80/00; H01L 2224/08145; H01L 2224/80895; H01L 2224/80896; H01L 2924/1431; H01L 2924/14511

(57) ABSTRACT

A semiconductor memory device includes a pillar structure of a first row and a pillar structure of a second row, which penetrate a gate structure, extend to the inside of a source structure, and are adjacent to each other. The source structure includes a first semiconductor layer and a second semiconductor layer, which are stacked between the pillar structure of the first row and the pillar structure of the second row, or includes a first doped region and a second doped region, which have different concentrations of a conductivity type dopant between the pillar structure of the first row and the pillar structure of the second row.

### CROSS-REFERENCE TO RELATED APPLICATION

The present application claims priority under 35 U.S.C. § 119(a) to Korean patent application number 10-2024-0059819 filed on May 7, 2024, in the Korean Intellectual Property Office, the entire contents of which application is incorporated herein by reference.

### BACKGROUND

### 1. Technical Field

The present disclosure generally relates to a semiconductor memory device and a semiconductor memory device of an electronic system, and more particularly, to a three-dimensional semiconductor memory device.

### 2. Related Art

Semiconductor memory devices are applied to electronic systems in various fields, including automobiles, medical appliances, data centers, and the like, in addition to compact electronic devices. Accordingly, the demand for semiconductor memory devices has increased.

A semiconductor memory device includes a memory cell array, and the memory cell array includes a plurality of memory cells for storing data. The semiconductor memory device is classified into a two-dimensional semiconductor memory device including a two-dimensional memory cell array and a three-dimensional semiconductor memory device including a three-dimensional memory cell array.

Memory cells having the three-dimensional memory cell array are arranged three-dimensionally. The three-dimensional memory cell array has the advantage of providing a large capacity for the semiconductor memory device whereas with the two-dimensional memory cell array the plurality of memory cells are arranged on a plane providing a smaller capacity.

### SUMMARY

In accordance with an embodiment of the present disclosure, there is provided a semiconductor memory device including: a gate structure including a surface extending in a first direction and a second direction, the first direction different from the second direction, the gate structure including insulating layers and conductive layers, the insulating layers and the conductive layers alternately disposed in a stacking direction protruding from the surface; a source structure overlapping with the gate structure; and a plurality of pillar structures penetrating the insulating layers and the conductive layers, the plurality of pillar structures extending to the inside of the source structure, wherein each of the plurality of pillar structures includes: a channel structure penetrating the insulating layers and the conductive layers, the channel structure extending to the inside of the source structure; and a memory layer between the channel structure and the gate structure, and wherein the source structure incudes: a first semiconductor layer including a bottom recessed portion into which the channel structure is inserted and a top recessed portion disposed between a pillar structure of a first row and a pillar structure of a second row, which are adjacent to each other, among the plurality of pillar structure; and a second semiconductor layer disposed over the first semiconductor layer to fill the top recessed portion.

In accordance with an embodiment of the present disclosure, there is provided a semiconductor memory device including: a gate structure including a surface extending in a first direction and a second direction, the first direction different from the second direction, the gate structure including insulating layers and conductive layers, the insulating layers and the conductive layers alternately disposed in a stacking direction protruding from the surface; a doped semiconductor structure overlapping with the gate structure, the doped semiconductor structure including a conductivity type dopant; and a plurality of pillar structures penetrating the insulating layers and the conductive layers, the plurality of pillar structures extending to the inside of the doped semiconductor structure, wherein each of the plurality of pillar structures includes: a channel structure penetrating the insulating layers and the conductive layers, the channel structure extending to the inside of the doped semiconductor structure; and a memory layer between the channel structure and the gate structure, wherein the doped semiconductor structure includes: a first doped region in contact with the channel structure, the first doped region including the conductivity type dopant at a first concentration; and a second doped region disposed over the first doped region, the second doped region including the conductivity type dopant at a second concentration different from the first concentration, and wherein a first thickness of the first doped region in the stacking direction and a second thickness of the second doped region in the stacking direction vary between a pillar structure of a first row and a pillar structure of a second row, which are adjacent to each other, among the plurality of pillar structures.

### BRIEF DESCRIPTION OF THE DRAWINGS

FIG. 1 is a block diagram illustrating a semiconductor memory device in accordance with an embodiment of the present disclosure.

FIG. 2A and FIG. 2B are plan views illustrating a semiconductor memory device in accordance with an embodiment of the present disclosure.

FIG. 3A, FIG. 3B, and FIG. 3C are sectional views of the semiconductor memory device shown in FIG. 2A.

FIG. 4A, FIG. 4B, and FIG. 4C are sectional views illustrating source structures in accordance with an embodiment of the present disclosure.

FIG. 5A, FIG. 5B, FIG. 6A, and FIG. 6B are sectional views illustrating a portion of a manufacturing method for providing a semiconductor memory device in accordance with an embodiment of the present disclosure.

FIG. 7A, FIG. 8A, FIG. 9A, and FIG. 10A are sectional views illustrating a manufacturing method of a semiconductor memory device in accordance with embodiments of the present disclosure, and each of FIG. 7A, FIG. 8A, FIG. 9A, and FIG. 10A illustrates a section of a structure for each unit process, taken along line I-I′ shown in FIG. 2A.

FIG. 7B, FIG. 8B, FIG. 9B, FIG. 10B, FIG. 11, FIG. 12, and FIG. 13 are sectional views illustrating a manufacturing method of a semiconductor memory device in accordance with an embodiment of the present disclosure, and each of FIG. 7B, FIG. 8B, FIG. 9B, FIG. 10B, FIG. 11, FIG. 12, and FIG. 13 illustrates a section of a structure for each unit process, taken along line II-II′ shown in FIG. 2A.

FIG. 14 is a block diagram illustrating an electronic system in accordance with an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Terms such as “first” and “second” are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “higher,” “column,” “row,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas.

Various embodiments provide a semiconductor memory device capable of improving operation reliability.

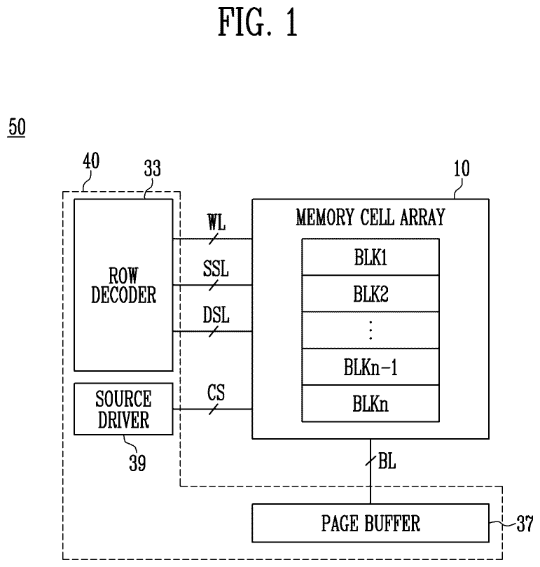

FIG. 1 is a block diagram illustrating a semiconductor memory device in accordance with an embodiment of the present disclosure.

Referring to FIG. 1, the semiconductor memory device 50 includes a peripheral circuit 40 and a memory cell array 10.

The peripheral circuit 40 is configured to perform a program operation for storing data in the memory cell array 10, a read operation for outputting data stored in the memory cell array 10, and an erase operation for erasing data stored in the memory cell array 10. The peripheral circuit 40 includes a row decoder 33, a page buffer 37, and a source driver 39.

The memory cell array 10 includes a plurality of memory blocks BLK1 to BLKn (n is a natural number of 2 or more). The plurality of memory blocks BLK1 to BLKn are connected to the page buffer 37 through a plurality of bit lines BL. The plurality of memory blocks BLK1 to BLKn are connected to the row decoder 33 through a plurality of drain select lines DSL, a plurality of word lines WL, and a plurality of source select lines SSL. The plurality of memory blocks BLK1 to BLKn are connected to the source driver 39 through a plurality of common source layers CS.

Each memory block includes a plurality of memory cells. The plurality of memory cells may be arranged in first to third directions different from one another, to constitute a three-dimensional memory cell array. Each memory block includes at least one source select line SSL, at least one drain select line DSL, and a plurality of word lines WL stacked between the at least one source select line SSL and the at least one drain select line DSL. Some of the plurality of word lines WL may be used as dummy word lines. An erase operation may be controlled in a common source layer (CS) unit. A common source layer CS may be connected to a memory block via a source structure.

The row decoder 33 transfers operating voltages to the plurality of drain select lines DSL, the plurality of word lines WL, and the plurality of source select lines SSL. The page buffer 37 controls the plurality of bit lines BL, or sense voltages or currents of the plurality of bit lines BL, thereby storing a sensed result. The source driver 39 controls the common source layers CS.

The memory cell array 10 may overlap with the peripheral circuit 40. The plurality of bit lines BL, the plurality of word lines WL, the plurality of drain select lines DSL, the plurality of source select lines SSL, and the plurality of common source layers CS, which are connected to the memory cell array 10, are electrically connected to the peripheral circuit 40 through conductive via structures.

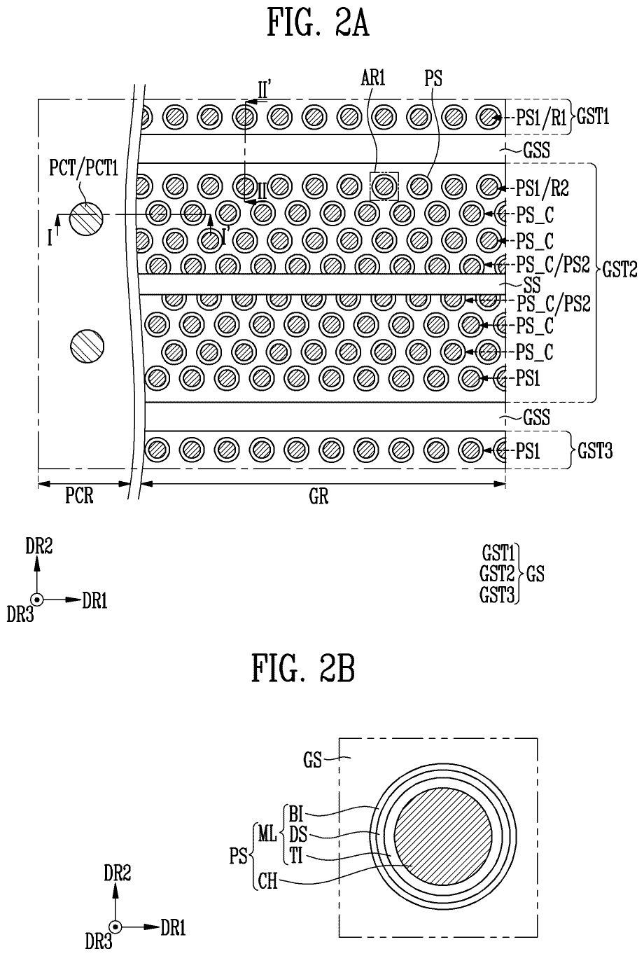

FIG. 2A and FIG. 2B are plan views illustrating a semiconductor memory device in accordance with an embodiment of the present disclosure.

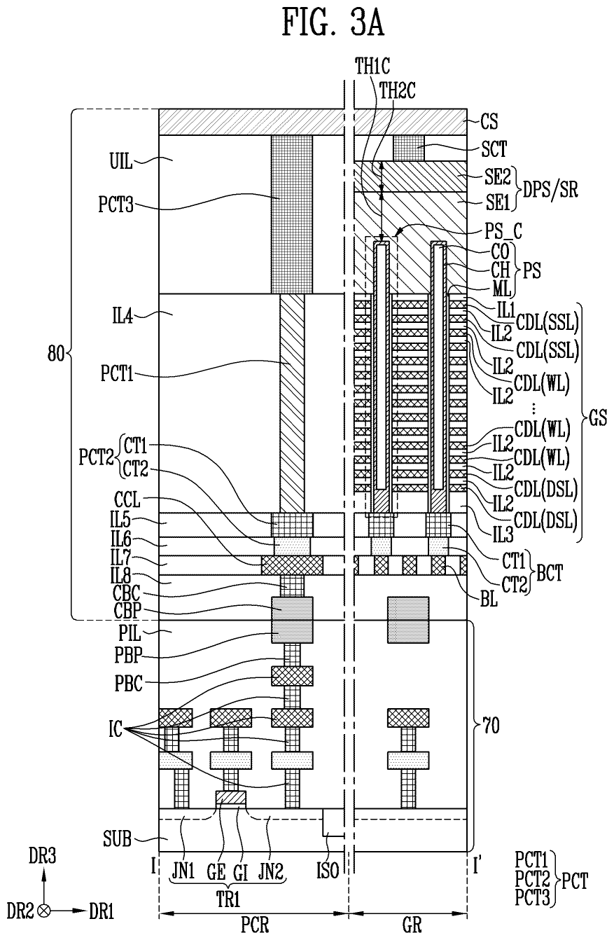

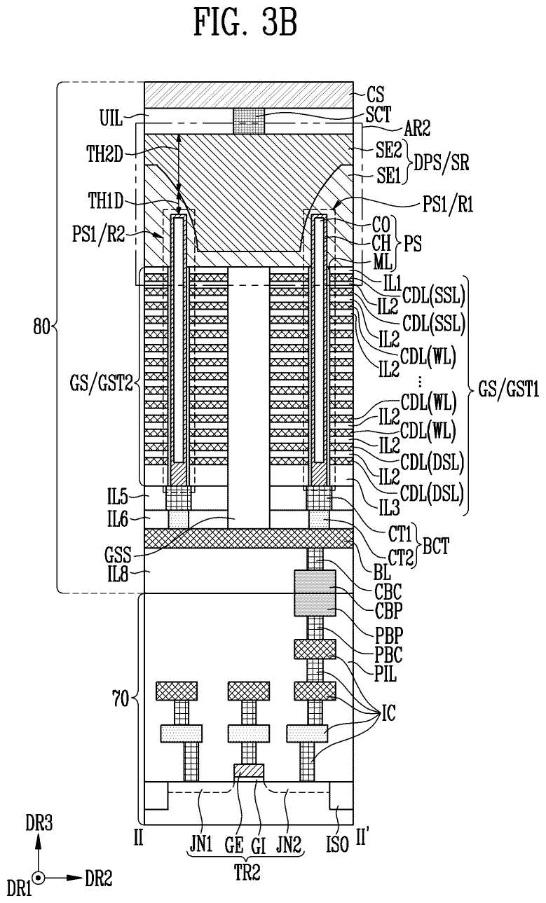

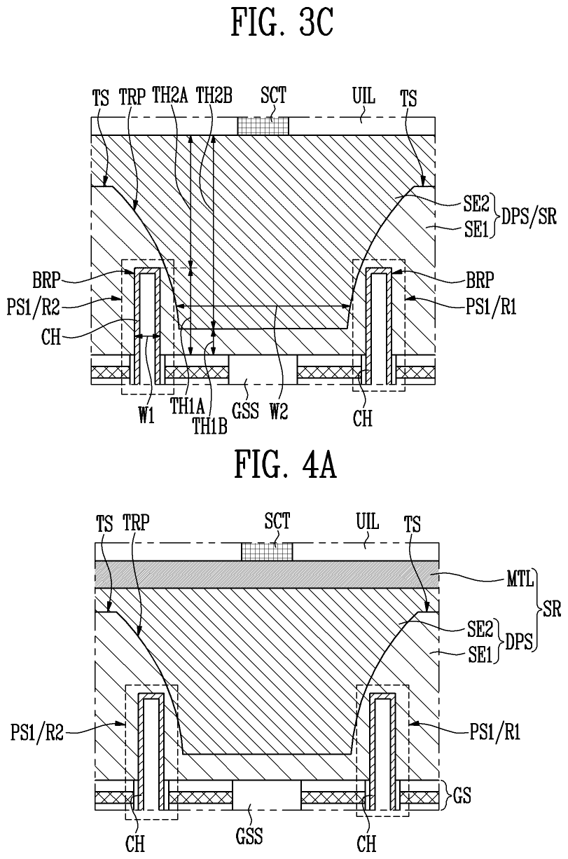

FIG. 3A, FIG. 3B, and FIG. 3C are sectional views of the semiconductor memory device shown in FIG. 2A.

Referring to FIG. 2A, FIG. 3A, and FIG. 3B, the semiconductor memory device includes a first structure 70 and a second structure 80 over the first structure 70. The first structure 70 may include some conductive via structures, such as interconnection structures IC, a peripheral circuit structure such as transistors TR1 and TR2, and the like. The second structure 80 includes other conductive via structures, such as peripheral circuit contact structures PCT, a gate structure GS of a memory cell array, and the like.

The first structure 70 overlaps with a gate region GR and a peripheral circuit contact region PCR of a semiconductor substrate SUB. The gate structure GS of the second structure 80 overlaps with the gate region GR, and the peripheral circuit contact structures PCT of the second structure 80 overlap with the peripheral circuit contact region PCR.

The gate structure GS includes insulating layers IL1, IL2, and IL3, and conductive layers CDL. Each of the insulating layers IL1, IL2, and IL3, and the conductive layers CDL includes a surface extending in a first direction DR1 and a second direction DR2, which are different from each other. The insulating layers IL1, IL2, and IL3, and the conductive layers CDL are alternately disposed in a third direction DR3 orthogonal to the surface of each thereof or, in an embodiment, the insulating layers IL1, IL2, and IL3, and the conductive layers CDL are alternately disposed in a stacking direction (i.e., the third direction DR3 etc.,) protruding from the surface of a plane formed by the first and second directions DR1 and DR2. In an embodiment, the first direction DR1, the second direction DR2, and the third direction DR3 may be an X-axis direction, a Y-axis direction, and a Z-axis direction.

Each peripheral circuit contact structure PCT includes a first peripheral contact plug PCT1 disposed at the same level as the gate structure GS.

FIG. 2A is a plan view illustrating a layout of the gate structure GS and the first peripheral contact plug PCT1 of the semiconductor memory device.

Referring to FIG. 2A, the gate structure GS is partitioned into gate stack structures GST1, GST2, and GST3 by gate isolation structures GSS. The gate stack structures GST1, GST2, and GST3 are spaced apart from each other in the second direction DR2. FIG. 2A illustrates a portion of each of a first gate stack structure GST1, a second gate stack structure GST2, and a third gate stack structure GST3 of the gate structure GS, and mainly illustrates the gate structure GS mainly with respect to the second gate stack structure GST2.

The gate structure GS is penetrated by a plurality of pillar structures PS. The plurality of pillar structures PS are divided into groups corresponding to each of the gate stack structures GST1, GST2, and GST3. In an embodiment, the plurality of pillar structures PS may include first to third groups, the first group among the plurality of pillar structures PS may penetrate the first gate stack structure GST1, the second group among the plurality of pillar structures PS may penetrate the second gate stack structure GST2, and the third group among the plurality of pillar structures PS may penetrate the third gate stack structure GST3.

Pillar structures PS of each group constitute a plurality of rows and a plurality of columns. Each row is configured with pillar structures PS arranged in a line in the first direction DR1, and each column is configured with pillar structures PS arranged in a line in the second direction DR2. FIG. 2A illustrates a portion of each of the first gate stack structure GST1 surrounding pillar structures of one row, which are adjacent to the second gate stack structure GST2, and the third gate stack structure GST3 surrounding pillar structures of another row, which are adjacent to the second gate stack structure GST2. Although not shown in the drawing, like the second gate stack structure GST2, each of the first gate stack structure GST1 and the third gate stack structure GST3 may surround pillar structures of a plurality of rows of a group corresponding thereto.

The pillar structures PS of each group include first pillar structures PS1 adjacent to the gate isolation structures GSS. Each gate isolation structure GSS is disposed between first pillar structures PS1 of groups adjacent to each other, and the first pillar structures PS1 of the groups adjacent to each other constitute rows adjacent to each other in the second direction DR2. In an embodiment, first pillar structures PS1 of the first group, which penetrate the first gate stack structure GST1, may include first pillar structures PS1 of a first row R1, and first pillar structures PS1 of the second group, which penetrate the second gate stack structure GST2, may include first pillar structures PS1 of a second row R2. The first row R1 and the second row R2 are spaced apart from each other with a gate isolation structure GSS between the first gate stack structure GST1 and the second gate stack structure GST2, which is interposed therebetween, and are adjacent to each other in the second direction DR2.

The pillar structures PS of each group further include center pillar structures PS_C. In the same group, center pillar structures PS_C are arranged distant from the gate isolation structure GSS as compared with the first pillar structures PS1. A width of the gate isolation structure GSS is defined in the second direction DR2. In the same group, pillar structures PS are arranged at a distance narrower than the width of the gate isolation structure GSS. Accordingly, in an embodiment, the arrangement density of pillar structures PS in each gate stack structure may be increased, and thus the degree of integration of the semiconductor memory device may be improved.

As described above, a distance between the first pillar structure PS1 of the first row R1 and the first pillar structure PS1 of the second row R2 is defined greater than a distance between the center pillar structures PS_C in each group and a distance between the first pillar structure PS1 and the center pillar structure PS_C in each group.

Each of the gate stack structures GST1, GST2, and GST3 includes a select isolation structure SS. The select isolation structure SS may be formed shorter in the third direction DR3 than the gate isolation structure GSS, and may be disposed inside a gate stack structure corresponding thereto. The select isolation structure SS and the gate isolation structure GSS extend in the first direction DR1. By the select isolation structure SS, some of conductive layers of each gate stack structure may be isolated into source select lines or drain select lines. The select isolation structure SS may include an insulating material.

The center pillar structures PS_C are arranged at both sides of the select isolation structure SS. In an embodiment, the select isolation structure SS may overlap with some of the center pillar structures PS_C. In other words, the center pillar structures PS_C may include second pillar structures PS2 overlapping with the select isolation structure SS. The second pillar structures PS2 are arranged along one side and the other side of the select isolation structure SS, which are adjacent to each other in the second direction DR2. However, embodiments of the present disclosure are not limited thereto. Although not shown in the drawing, in an embodiment, the pillar structures PS may further include dummy pillar structures overlapping with the select isolation structure SS, and the center pillar structures PS_C may be arranged at both sides of a row configured with the dummy pillar structures not to overlap with the select isolation structure SS.

FIG. 2B is an enlarged plan view of region “AR1” shown in FIG. 2A.

Referring to FIG. 2B, each pillar structure PS includes a channel structure CH and a memory layer ML. The channel structure CH extends in the third direction DR3 to penetrate the gate structure GS. The memory layer ML is interposed between the channel structure CH and the gate structure GS.

The memory layer ML includes a tunnel insulating layer TI, a data storage layer DS, and a blocking insulating layer BI. The tunnel insulating layer TI extends along an outer wall of the channel structure CH. The tunnel insulating layer TI includes an insulating material such as a silicon oxide layer. The data storage layer DS is interposed between the gate structure GS and the tunnel insulating layer TI. In an embodiment, the data storage layer DS may continuously extend along an outer wall of the tunnel insulating layer TI. In another embodiment, the data storage layer DA may be isolated into a plurality of data storage patterns spaced apart from each other in the third direction DR3, and each data storage pattern may be disposed between the channel structure CH and a conductive layer corresponding thereto among the conductive layers CDL shown in FIG. 3A or 3B. The data storage layer DS may be formed of a material layer capable of storing data changed using Fowler-Nordheim tunneling. In an embodiment, the data storage layer DS may be formed of a charge trap insulating layer, be formed of a floating gate layer, or be formed of an insulating layer including a conductive nano dot. The charge trap insulating layer may include a silicon nitride layer. The blocking insulating layer BI is interposed between the gate structure GS and the data storage layer DS. The blocking insulating layer BI includes at least one of a silicon dioxide layer (SiO₂) and a high dielectric layer having a dielectric constant higher than a dielectric constant of the silicon dioxide layer. The high dielectric layer may include an aluminum oxide layer, a hafnium oxide layer, and the like.

FIG. 3A is a sectional view of the semiconductor memory device taken along line I-I′ shown in FIG. 2A, and FIG. 3B is a sectional view of the semiconductor memory device taken along line II-II′ shown in FIG. 2A.

Referring to FIG. 3A and FIG. 3B, the first structure 70 includes peripheral circuit-side bonding pads PBP bonded to the second structure 80, peripheral circuit-side bonding contacts PBC connecting the interconnection structures IC to the peripheral circuit-side bonding pads PBP, and a peripheral circuit-side insulating structure PIL, in addition to the peripheral circuit structure including the transistors TR1 and TR2 and the interconnection structures IC, which are described above. The peripheral circuit-side insulating structure PIL is disposed over the semiconductor substrate SUB to cover the transistors TR1 and TR2, the interconnection structures IC, the peripheral circuit-side bonding pads PBP, and the peripheral circuit-side bonding contacts PBC. The interconnection structures IC, the peripheral circuit-side bonding pads PBP, and the peripheral circuit-side bonding contacts PBC are used as conductive via structures.

Each of the transistors TR1 and TR2 includes a gate insulating layer GI, a gate electrode GE, a first junction JN1, and a second junction JN2. The gate insulating layer GI and the gate electrode GE are stacked over an active region of the semiconductor substrate SUB. The active region of the semiconductor substrate SUB is partitioned by an isolation structure ISO disposed in the semiconductor substrate SUB. The first junction JN1 and the second junction JN2 are disposed in the active region at both sides of the gate electrode GE, and are used as a source region and a drain region. The transistors TR1 and TR2 may include a first transistor TR1 of the source driver 39 shown in FIG. 1 and a second transistor TR2 of the page buffer 37 shown in FIG. 1.

The interconnection structures IC are configured with conductive patterns constituting lines and contact plugs. The interconnection structures IC are electrically connected to the peripheral circuit structure. The interconnection structures IC include structures of a first group, which are respectively connected to a gate electrode GE, a first junction JN1, and a second junction JN2 of the first transistor TR1, and structure of a second group, which are respectively connected to a gate electrode GE, a first junction JN1, and a second junction JN2 of the second transistor TR2.

The peripheral circuit-side bonding contacts PBC extend in the third direction DR3 from some of the interconnection structures IC. The peripheral circuit-side bonding contacts PBC are respectively connected to some of the structures of the first and second groups among the interconnection structures IC. In an embodiment, the interconnection structures IC may include a first interconnection structure electrically connected to the second junction JN2 of the first transistor TR1 and a second interconnection structure electrically connected to the second junction JN2 of the second transistor TR2, and the peripheral circuit-side bonding contacts PBC may include a contact in contact with the first interconnection structure and a contact in contact with the second interconnection structure. The peripheral circuit-side bonding contacts PBC includes a conductive material such as a metal.

The peripheral circuit-side insulating structure PIL includes insulating layers including at least two layers.

The peripheral circuit-side bonding pads PBP are disposed in an uppermost insulating layer of the peripheral circuit-side insulating structure PIL. A top surface of each of the peripheral circuit-side bonding pads PBP might not be covered by the peripheral circuit-side insulating structure PIL. The peripheral circuit-side bonding pads PBP include a bonding metal such as copper, aluminum or tungsten. Some of the peripheral circuit-side bonding pads PBP may be electrically connected to the peripheral circuit structure via some of the peripheral circuit-side bonding contacts PBC and the interconnection structures IC. In an embodiment, the peripheral circuit-side bonding pads PBP may include a first bonding pad electrically connected to the second junction JN2 of the first transistor TR1 and a second bonding pad electrically connected to the second junction JN2 of the second transistor TR2. The first bonding pad may be electrically connected to the first transistor TR1 via the first interconnection structure among the interconnection structures IC through any one of the peripheral circuit-side bonding contacts PBC. The second bonding pad may be electrically connected to the second transistor TR2 via the second interconnection structure among the interconnection structures IC through another of the peripheral circuit-side bonding contacts PBC.

The second structure 80 includes pillar structures PS of the memory cell array, a plurality of bit lines BL between the gate structure GS and the first structure 70, connection lines CCL between the peripheral circuit contact structures PCT and the first structure 70, bit line connection structures BCT electrically connecting the pillar structures PS to the plurality of bit lines BL, cell-side bonding pads CBP bonded to the first structure 70, cell-side bonding contacts CBC, a source structure SR over the gate structure GS, and an upper conductive pattern (e.g., CS) over the source structure SR, in addition to the gate structure GS, the gate isolation structure GSS, and the peripheral circuit contact structures PCT, which are described above. The peripheral circuit contact structures PCT, the connection lines CCL, the cell-side bonding pads CBP, and the cell-side bonding contacts CBC are used as conductive via structures. Each of the peripheral circuit contact structures PCT may include a second peripheral contact plug PCT2 and a third peripheral contact plug PCT3, in addition to the above-described first peripheral contact plug PCT1.

The gate isolation structure GSS extends in the third direction DR3 to penetrate the insulating layers IL1, IL2, and IL3 and the conductive layers CDL of the gate structure GS. Accordingly, the insulating layers IL1, IL2, and IL3 and the conductive layers CDL are partitioned to constitute each gate stack structure (e.g., GST1 or GST2).

The insulating layers IL1, IL2, and IL3 of the gate structure GS include a first insulating layer IL1, second insulating layers IL2, and a third insulating layer IL3. The first insulating layer IL1 is disposed adjacent to the source structure SR, and the third insulating layer IL3 is spaced apart from the first insulating layer IL1 with the conductive layers CDL interposed therebetween. The second insulating layers IL2 are disposed between the first insulating layers IL1 and the third insulating layer IL3, and are alternately disposed one by one in the third direction DR3 with the conductive layers CDL. Accordingly, conductive layers CDL adjacent to each other in the third direction DR3 are spaced apart from each other by a second insulating layer IL2 therebetween. However, the embodiment of the present disclosure is not limited thereto. In an embodiment, conductive layers CDL adjacent to each other in the third direction DR3 may be spaced apart from each other by an air gap therebetween.

At least one of the conductive layers CDL of the gate structure GS may be used as a source select line SSL, at least another of the conductive layers CDL of the gate structure GS may be used as a drain select line DSL, and the others of the conductive layers CDL of the gate structure GS may be used as a plurality of word lines WL. Each of the conductive layers CDL include various conductive materials such as a doped semiconductor layer and a metal layer. The doped semiconductor layer may include a doped silicon layer. The metal layer may include tungsten, copper, molybdenum, and the like. Each conductive layer CDL further includes a metal nitride layer. The metal nitride layer may include titanium nitride, tantalum nitride, molybdenum nitride, and the like. The first insulating layer IL1, the second insulating layers IL2, and the third insulating layer IL3 include an insulating material such as a silicon oxide layer (e.g., SiO₂) or a silicon oxynitride layer (SiON).

At least one of a source select line SSL and a drain select line DSL of each gate stack structure (e.g., GST1 or GST2) may be partitioned narrower than each word line WL by the select isolation structure SS shown in FIG. 2A. Each word line WL is not isolated by the select isolation structure SS but may extend to overlap with the select isolation structure SS.

The pillar structures PS extend to the inside of the source structure SR. More specifically, a channel structure CH of the pillar structure PS extends to the inside of the source structure SR while penetrating the gate structure GS. A memory layer ML of the pillar structure PS is interposed between the gate structure GS and the channel structure CH. The channel structure CH is formed longer in the third direction DR3 than the memory layer ML. The channel structure CH is formed of a semiconductor material to be used as a channel region of a memory cell string, and the semiconductor material includes silicon (Si), germanium (Ge), any mixture thereof, or the like. The channel structure CH has various shapes. In an embodiment, a central region of the channel structure CH may be filled with a core insulating layer CO. Each of end portions of the channel structure CH, which face the bit line BL and the source structure SR, include at least one of an n-type impurity and a p-type impurity. In an embodiment, each of the end portions of the channel structure CH may be configured as an n-type doped region including the n-type impurity as a majority carrier.

A plurality of memory cell strings of the memory cell array 10 described with reference to FIG. 1 are arranged in the first direction DR1 and the second direction DR2, like the arrangement of the pillar structures PS. Each memory cell string includes a plurality of memory cells formed at intersection portions of the channel structure CH and the plurality of word lines WL, a source select transistor formed at an intersection portion of the channel structure CH and the source select line SSL, and a drain select transistor formed at an intersection portion of the channel structure CH and the drain select line DSL. The source select transistor, the plurality of memory cells, and the drain select transistor are connected in series by the channel structure CH to form the memory cell string. Accordingly, each of the plurality of memory cell strings includes a plurality of memory cells arranged along the third direction DR3. Because the plurality of memory strings are arranged in the first direction DR1 and the second direction DR2, a three-dimensional memory cell array including three-dimensionally arranged memory cells is provided.

The second structure 80 includes a fourth insulating layer IL4 disposed at the same level as the gate structure GS. The fourth insulating layer IL4 overlaps with the peripheral circuit contact region PCR. The first peripheral contact plug PCT1 of the peripheral circuit contact structure PCT is formed of a conductive material penetrating the fourth insulating layer IL4.

The second structure 80 further includes insulating layers including at least two layers, which are disposed between the fourth insulating layer IL4 and the first structure 70. In an embodiment, the second structure 80 may further include fifth to eighth insulating layers IL5 to IL8 sequentially disposed between the fourth insulating layer IL4 and the first structure 70.

Each of the fifth insulating layer IL5 and the sixth insulating layer IL6 extends in the first direction DR1 and the second direction DR2 to overlap with the fourth insulating layer IL4 and the gate structure GS. The fifth insulating layer IL5 is penetrated by a plurality of first contact plugs CT1 formed of a conductive material, and the sixth insulating layer IL6 is penetrated by a plurality of second contact plugs CT2 formed of a conductive material.

Some of the plurality of first contact plugs CT1 and some of the plurality of second contact plugs CT2 may constitute the bit line connection structures BCT. Others of the plurality of first contact plugs CT1 and others of the plurality of second contact plugs CT2 may constitute the second peripheral contact plug PCT2. Each of the bit line connection structures BCT is in contact with a channel structure CH of a pillar structure corresponding thereto. The second peripheral contact plug PCT2 is in contact with the first peripheral contact plug PCT1.

The gate isolation structure GSS extends to penetrate the fifth insulating layer IL5 and the sixth insulating layer IL6. The gate isolation structure GSS includes an insulating layer covering sidewall of each gate stack structure (e.g., GST1 or GST2). In an embodiment, the gate isolation structure GSS may be configured with a single insulating layer. In another embodiment, the gate isolation structure GSS may include an insulating layer and a core material disposed in a central region of the gate isolation structure GSS, which is opened by the insulating layer. The core material may include at least one of a semiconductor material and a conductive material. The semiconductor material may include at least one of an undoped semiconductor layer and a doped semiconductor layer. The doped semiconductor layer may include at least one of an n-type impurity and a p-type impurity. The conductive material may include a metal, a metal nitride, and the like.

The seventh insulating layer IL7 is interposed between the eighth insulating layer IL8 and the sixth insulating layer IL6, and extends in the first direction DR1 and the second direction DR2. The seventh insulating layer IL7 is penetrated by the connection lines CCL and the plurality of bit lines BL. The connection lines CCL and the plurality of bit lines BL include a conductive material such as a metal. Each connection line CCL may be in contact with a second peripheral contact plug PCT2 corresponding thereto. The plurality of bit lines BL is arranged to be spaced apart from each other in the first direction DR1. Each bit line BL extends in the second direction DR2. The bit line BL overlaps with gate stack structures (e.g., GST1 and GST2) adjacent to each other. Pillar structures PS penetrating different gate stack structure are connected in parallel to the same bit line BL.

The cell-side bonding pads CBP and the cell-side bonding contacts CBC are disposed in the eighth insulating layer IL8. The cell-side bonding pads CBP are bonded to the peripheral circuit-side bonding pads PBP. Each of the cell-side bonding pads CBP includes a bonding surface facing peripheral circuit-side bonding pads PBP corresponding thereto. The bonding surface might not be covered by the eighth insulating layer IL8. The cell-side bonding pads CBP includes a bonding metal such as copper, aluminum or tungsten. Some of the cell-side bonding pads CBP may be electrically connected to the plurality of bit lines BL and the connection lines CCL via the cell-side bonding contacts CBC. In an embodiment, the cell-side bonding pads CBP may include first bonding pads respectively connected to the connection lines CCL and second bonding pads respectively connected to the plurality of bit lines BL.

The source structure SR is configured as a doped semiconductor structure DPS including a conductivity type dopant. The source structure SR extends in the first direction DR1 and the second direction DR2 to overlap with the gate structure GS and the gate isolation structure GSS.

FIG. 3C is an enlarged sectional view of region “AR2” shown in FIG. 3B.

Referring to FIG. 3A, FIG. 3B, and FIG. 3C, the source structure SR includes a first semiconductor layer SE1 and a second semiconductor layer SE2 over the first semiconductor layer SE1. The first semiconductor layer SE1 is provided as a first doped region, and the second semiconductor layer SE2 is provided as a second doped region. Each of the first semiconductor layer SE1 and the second semiconductor layer SE2 may include at least one of an n-type impurity and a p-type impurity. The first semiconductor layer SE1 constituting the first doped region includes a conductivity type dopant at a first concentration, and the second semiconductor layer SE2 constituting the second doped region includes the conductivity type dopant at a second concentration different from the first concentration. In an embodiment, the second concentration is higher than the first concentration.

A majority carrier of the first semiconductor layer SE1 and a majority carrier of the second semiconductor layer SE2 have the same conductivity type impurity. A concentration difference in conductivity type dopant in the first semiconductor layer SE1 and the second semiconductor layer SE2 is defined as a concentration difference in majority carrier. In an embodiment, each of the first semiconductor layer SE1 and the second semiconductor layer SE2 may include an n-type impurity as the majority carrier, and a concentration of the majority carrier in the second semiconductor layer SE2 may be higher than a concentration of the majority carrier in the first semiconductor layer SE1.

Each of the first semiconductor layer SE1 and the second semiconductor layer SE2 extends in the first direction DR1 and the second direction DR2 to overlap with the plurality of pillar structures PS including the first pillar structures PS1 and the center pillar structures PS_C. The second semiconductor layer SE2 is spaced apart from the plurality of pillar structures PS, the gate structure GS, and the gate isolation structure GSS by the first semiconductor layer SE1. In other words, the first semiconductor layer SE1 is interposed between the second semiconductor layer SE2 and each of the plurality of pillar structures PS, the gate structure GS, and the gate isolation structure GSS.

The first semiconductor layer SE1 is in contact with the channel structure CH. In an embodiment, a concentration of a conductivity type dopant or a concentration of a majority carrier is controlled to be lower in the first semiconductor layer SE1 in contact with the channel structure CH than the second semiconductor layer SE2 spaced apart from the channel structure CH, so that Gate Induced Drain Leakage (GIDL) may be reduced. The conductivity type dopant or the majority carrier is n-type dopant or p-type dopant.

The first semiconductor layer SE1 includes a bottom recessed portion BRP and a top recessed portion TRP. The channel structure CH is inserted into the bottom recessed portion BRP, and is in contact with the first semiconductor layer SE1 along the bottom recessed portion BRP. The top recessed portion TRP is disposed between the first pillar structure PS1 of the first row R1 (i.e., PS1/R1) and the first pillar structure PS1 of the second row R2 (i.e., PS1/R2). A width W2 of the top recessed portion TRP is greater than a width W1 of the bottom recessed portion BRP.

As a first thickness of the first semiconductor layer SE1 in the third direction DR3 varies, the top recessed portion TRP of the first semiconductor layer SE1 is defined. Between the first pillar structure PS1 of the first row R1 and the first pillar structure PS1 of the second row R2, the first thickness of the first semiconductor layer SE1 decreases as this first thickness is measured closer to the gate isolation structure GSS. For example, between the first pillar structure PS1 of the first row R1 and the first pillar structure PS1 of the second row R2, the first thickness may be formed with a value of “TH1A” in a first region of the source structure SR, which is adjacent to any one of the first pillar structures PS1, and may be formed with a value of “TH1B” in a second region of the source structure SR, which is closer to the gate isolation structure GSS than the first region. The value of “TH1B” is smaller than the value of “TH1A.”

The first semiconductor layer SE1 may fill a space between the center pillar structure PS_C disposed at a distance narrower than a distance between the first pillar structure PS1 of the first row R1 and the first pillar structure PS1 of the second row R2. The first thickness of the first semiconductor layer SE1 may be formed with a value of “TH1C” on the top of each of the center pillar structures PS_C, and be formed with a value of “TH1D” on the top of each of the first pillar structure PS1 of the first row R1 and the first pillar structure PS1 of the second row R2. The value of “TH1C” is greater than the value of “TH1D.”

The second semiconductor layer SE2 is disposed over the first semiconductor SE1 to fill the top recessed portion TRP. A second thickness of the second semiconductor layer SE2 in the third direction DR3 may vary between the first pillar structure PS1 of the first row R1 and the first pillar structure PS1 of the second row R2. Between the first pillar structure PS1 of the first row R1 and the first pillar structure PS1 of the second row R2, the second thickness of the second semiconductor layer SE2 increases when measured closer to the gate isolation structure GSS. For example, between the first pillar structure PS1 of the first row R1 and the first pillar structure PS1 of the second row R2, the second thickness may be formed with a value of “TH2A” in a first region of the source structure SR, which is adjacent to any one of the first pillar structures PS1, and may be formed with a value of “TH2B” in a second region of the source structure SR, which is closer to the gate isolation structure GSS than the first region. The value of “TH2B” is greater than the value of “TH2A.”

The second thickness of the second semiconductor layer SE2 may be formed with a value of “TH2C” on the top of each of the center pillar structures PS_C, and be formed with a value of “TH2D” on the top of each of the first pillar structure PS1 of the first row R1 and the first pillar structure PS1 of the second row R2. The value of “TH2C” is smaller than the value of “TH2D.”

Because the second thickness of the second semiconductor layer SE2 varies with a tendency opposite to a tendency of the first thickness of the first semiconductor layer SE1, the surface roughness of the first semiconductor layer SE1, which is caused by a difference in arrangement density of the pillar structures PS, may be compensated by the second semiconductor layer SE2. In an embodiment, a sum of the first thickness of the first semiconductor layer SE1 and the second thickness of the second semiconductor layer SE2 may be constant in various regions of the source structure SR.

The second semiconductor layer SE2 is in contact with a metal containing structure. A concentration of a conductivity type dopant or a concentration of a majority carrier is controlled to be higher in the second semiconductor layer SE2 than the first semiconductor layer SE1, so that an ohmic contact may be formed by contact between the second semiconductor layer SE2 and the metal containing structure. Accordingly, in an embodiment, the operation reliability of the semiconductor memory device may be improved.

In an embodiment, the second semiconductor layer SE2 may be in contact with a source contact plug SCT including a metal. The source contact plug SCT is formed in an upper insulating layer UIL covering the source structure SR. The source contact plug SCT electrically connects a common source layer CS over the upper insulating layer UIL and the source structure SR to each other.

The first semiconductor layer SE1 includes a top surface TS higher than a bottom of the top recessed portion TRP. The second semiconductor layer SE2 extends to cover the top surface TS of the first semiconductor layer SE1. Accordingly, the upper insulating layer UIL is spaced apart from the top surface TS of the first semiconductor layer SE1 with the second semiconductor layer SE2 interposed therebetween.

The upper insulating layer UIL extends to overlap with the peripheral circuit contact region PCR of the semiconductor substrate SUB, and the fourth insulating layer IL4 overlaps with the upper insulating layer UIL. A partial region of the upper insulating layer UIL, which overlaps with the peripheral circuit contact region PCR of the semiconductor substrate SUB, is penetrated by the third peripheral contact plug PCT3 of the peripheral circuit contact structure PCT. The third peripheral contact plug PCT3 is connected to the first peripheral contact plug PCT1.

The common source layer CS includes a conductive material such as a metal. The common source layer CS extends to be in contact with a third peripheral contact plug PCT3 of a corresponding peripheral contact structure among the peripheral circuit contact structures PCT. Accordingly, the common source layer CS is electrically connected to the first transistor TR1 via the first to third peripheral contact plugs PCT1 to PCT3 of the peripheral circuit contact structure PCT, the connection lines CCL, the cell-side bonding contact CBC, the cell-side bonding pad CBP, the peripheral circuit-side bonding pad PBP, the peripheral circuit-side bonding contact PBC, and the interconnection structure IC.

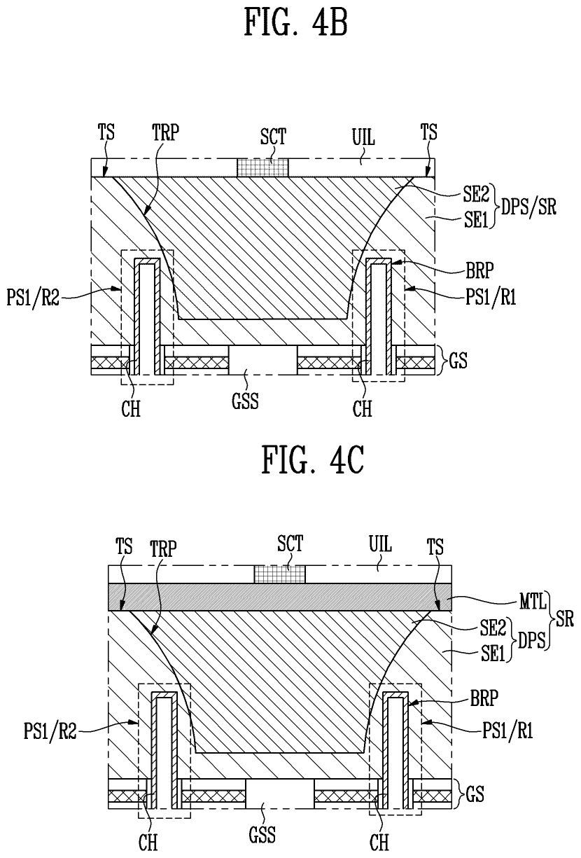

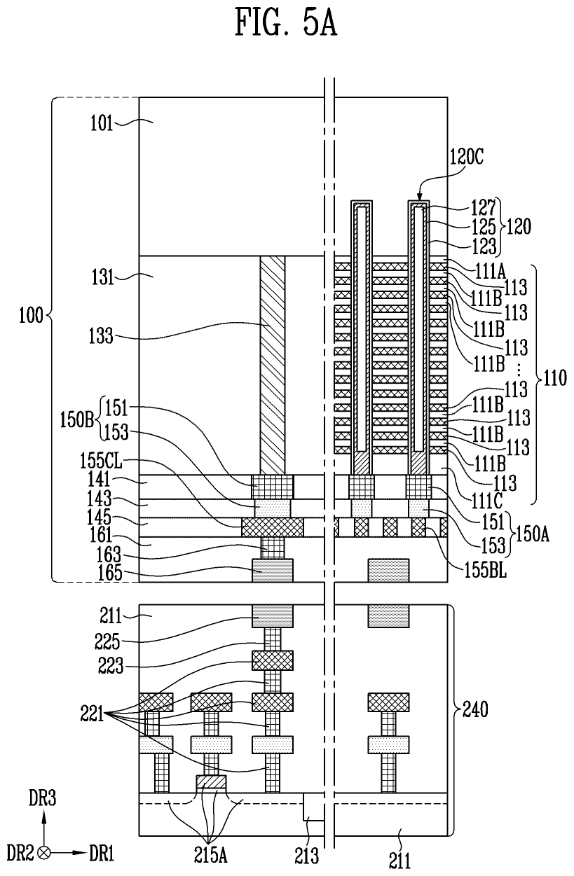

FIG. 4A, FIG. 4B, and FIG. 4C are sectional views illustrating source structures in accordance with an embodiment of the present disclosure. Hereinafter, descriptions of portions overlapping with those described with reference to FIG. 3A to FIG. 3C will be omitted or simplified.

Referring to FIG. 4A, a source structure SR may include a doped semiconductor structure DPS and a metal layer MTL over the doped semiconductor structure DPS. The doped semiconductor structure DPS includes a first semiconductor layer SE1 in contact with the channel structure CH and a second semiconductor layer SE2 over the first semiconductor layer SE1 as described with reference to FIG. 3A to FIG. 3C. The metal layer MTL is disposed over the second semiconductor layer SE2, and is connected to the second semiconductor layer SE2. In an embodiment, the resistivity of the source structure may be decreased by the metal layer MTL, and thus the operation reliability of the semiconductor memory device may be improved.

The metal layer MTL overlaps with a partial region of the second semiconductor layer SE2, which is disposed between the first pillar structure PS1 of the first row R1 and the first pillar structure PS1 of the second row R2. The first semiconductor layer SE1 includes a top surface TS higher than a bottom of the top recessed portion TRP. The metal layer MTL extends to both sides of a top recessed portion TRP to overlap with the top surface TS of the first semiconductor layer SE1.

Each of the first semiconductor layer SE1 and the second semiconductor layer SE2 is interposed between the gate isolation structure GSS and the metal layer MTL, and extends between the gate structure GS and the metal layer MTL. A concentration of a conductivity type dopant or a concentration of a majority carrier is controlled to be higher in the second semiconductor layer SE2 than the first semiconductor layer SE1, so that an ohmic contact between the metal layer MTL and the second semiconductor layer SE2 may be formed.

The upper insulating layer UIL is disposed over the metal layer MTL, and the source contact plug SCT is connected to the metal layer MTL.

Referring to FIG. 4B and FIG. 4C, each source structure SR includes a doped semiconductor structure DPS (i.e., DPS/SR). The doped semiconductor structure DPS includes a first semiconductor layer SE1 in contact with the channel structure CH and a second semiconductor layer SE2 over the first semiconductor layer SE1.

The first semiconductor layer SE1 overlaps with the first pillar structure PS1 of the first row R1 and the first pillar structure PS1 of the second row R2 as described with reference to FIG. 3A to FIG. 3C, and extends to overlap with the center pillar structures PS_C shown in FIG. 2A. The first semiconductor layer SE1 includes a top recessed portion TRP defined between the first pillar structure PS1 of the first row R1 and the first pillar structure PS1 of the second row R2, and extends to overlap with the gate structure GS and the gate isolation structure GSS.

The second semiconductor layer SE2 is formed to fill the top recessed portion TRP of the first semiconductor layer SE1. The second semiconductor layer SE2 does not overlap with a top surface TS of the first semiconductor layer SE1, which extends to both sides of the top recessed portion TRP, and the center pillar structures PS_C shown in FIG. 2A. Accordingly, the top surface TS of the first semiconductor layer SE1 is not covered by the second semiconductor layer SE2, but is opened at both sides of the second semiconductor layer SE2. For example, the top surface TS of the first semiconductor layer SE1 is opened at both sides of the second semiconductor layer SE2 as shown in FIGS. 4B and 4C then overlapped by the upper insulating layer UIL and/or the metal layer MTL.

Referring to FIG. 4B, the second semiconductor layer SE2 and the top surface TS of the first semiconductor layer SE1 are covered by the upper insulating layer UIL. A position of the source contact plug SCT may be controlled not to be in contact with the top surface TS of the first semiconductor layer SE1 but to be in contact with the second semiconductor layer SE2.

Referring to FIG. 4C, the source structure SR further includes a metal layer MTL over the doped semiconductor structure DPS. The metal layer MTL overlaps with the second semiconductor layer SE2, and extends to overlap with the top surface TS of the first semiconductor layer SE1. The upper insulating layer UIL is disposed over the metal layer MTL, and the source contact plug SCT is connected to the metal layer MTL.

Referring to FIG. 3C and FIG. 4A to FIG. 4C, the top recessed portion TRP of the first semiconductor layer SE1 is disposed between the first pillar structure PS1 of the first row R1 and the first pillar structure PS1 of the second row R2. As a result, a thickness of the first semiconductor layer SE may be formed partially thin between the first pillar structure PS1 of the first row R1 and the first pillar structure PS1 of the second row R2. In accordance with various embodiments of the present disclosure, a decrease in the thickness of the first semiconductor layer SE1 may be compensated through the second semiconductor layer SE2, and thus a thickness of the doped semiconductor structure DPS may be secure between the first pillar structure PS1 of the first row R1 and the first pillar structure PS1 of the second row R2. Accordingly, in an embodiment, a threshold voltage characteristic of a source select transistor adjacent to an end portion of each of the first pillar structure PS1 of the first row R1 and the first pillar structure PS1 of the second row R2, which face the source structure SR, may be stably secured, and thus, the operation reliability of the semiconductor memory device may be improved.

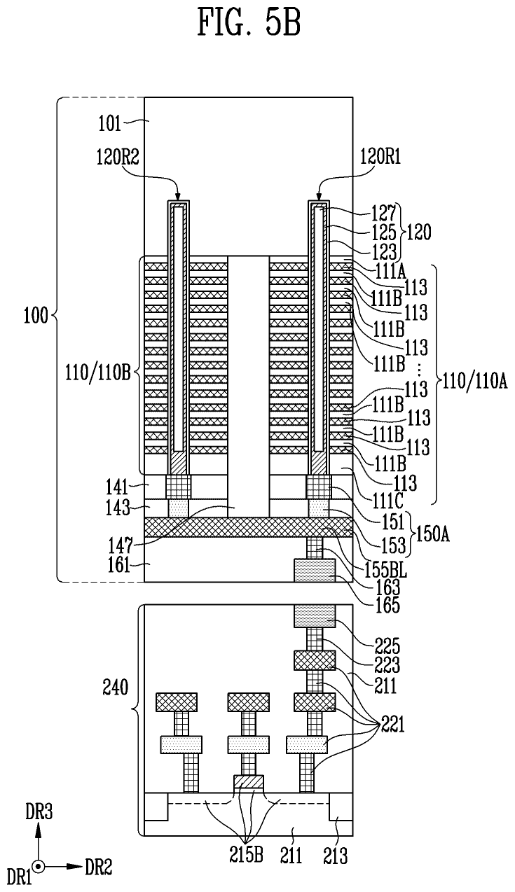

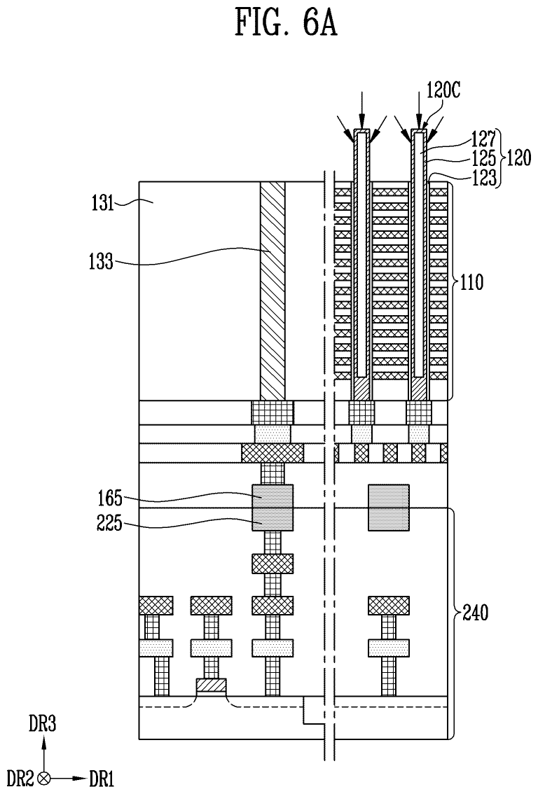

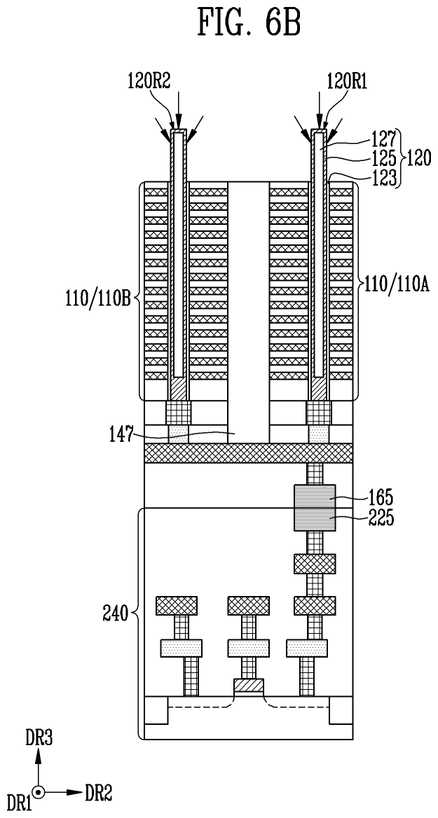

FIG. 5A, FIG. 5B, FIG. 6A, and FIG. 6B are sectional views illustrating a portion of a manufacturing method for providing a semiconductor memory device in accordance with an embodiment of the present disclosure.

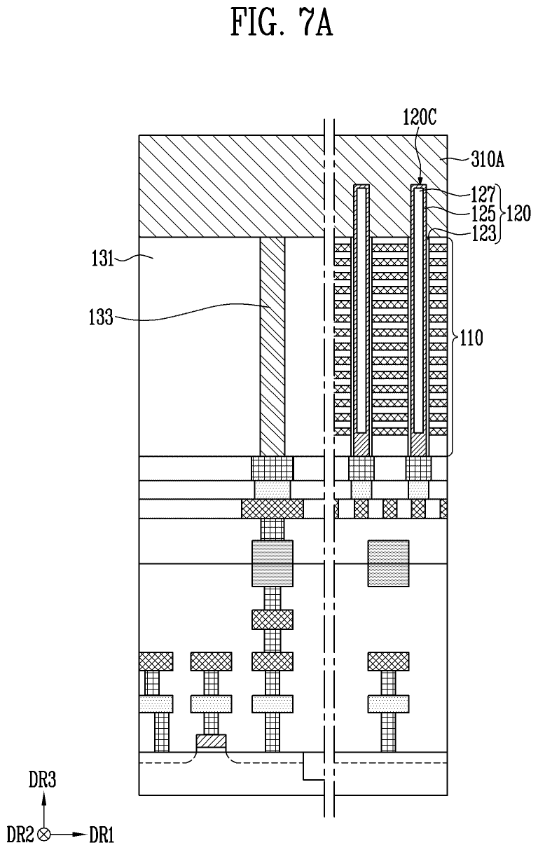

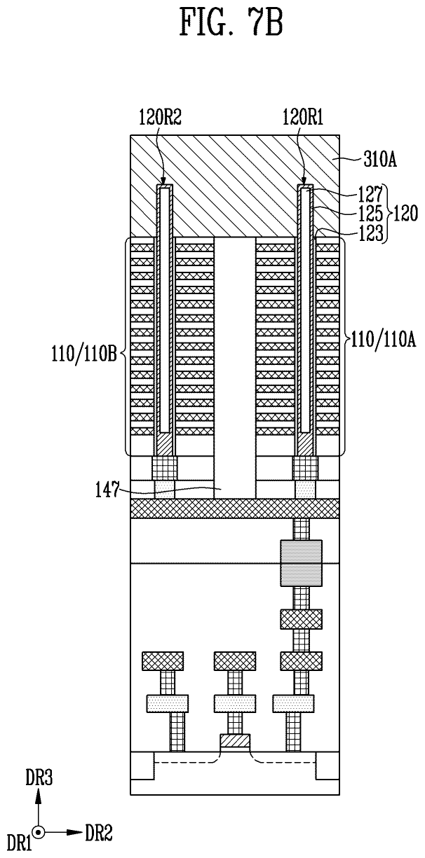

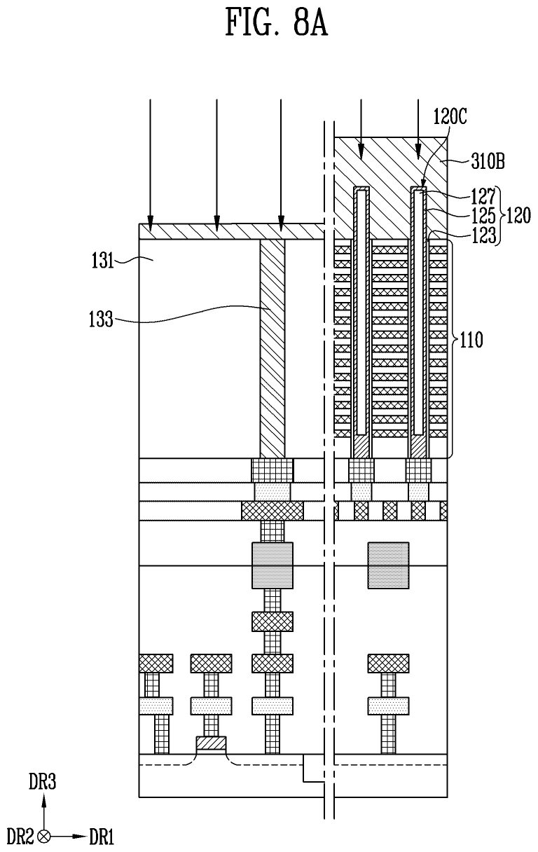

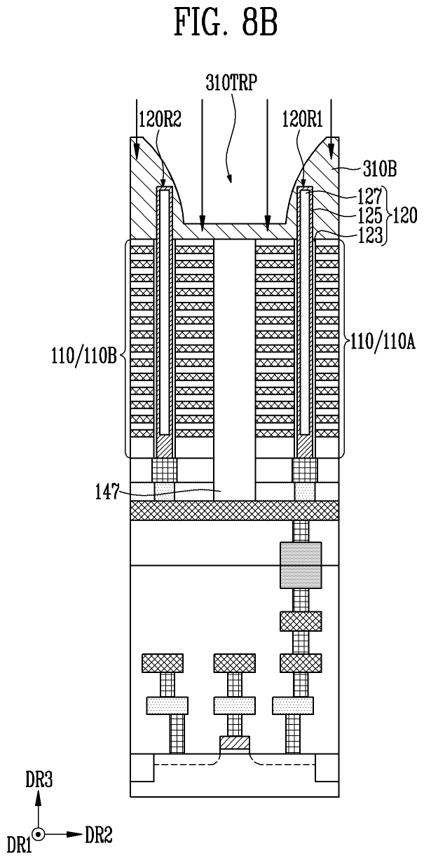

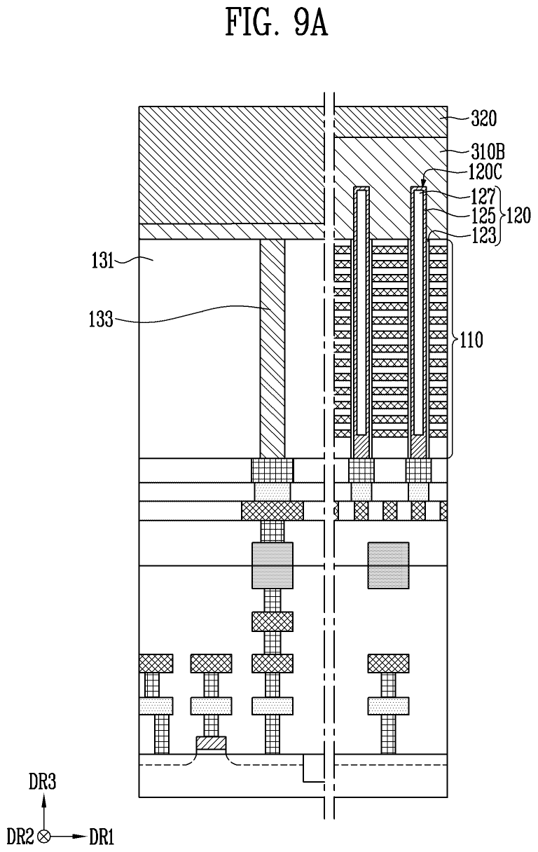

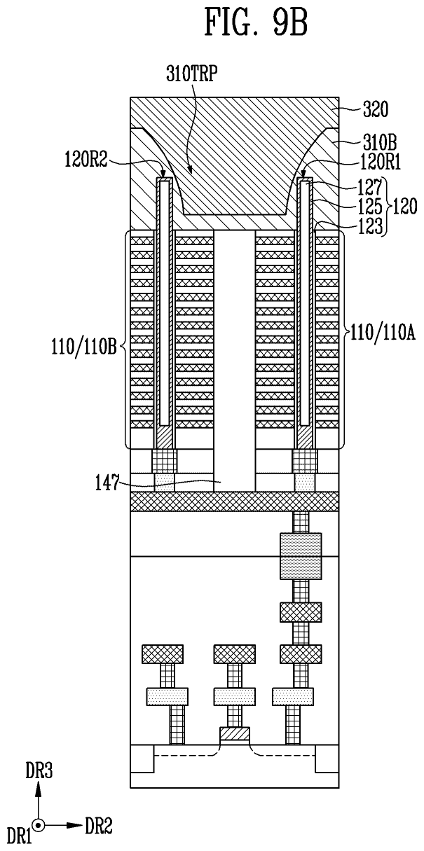

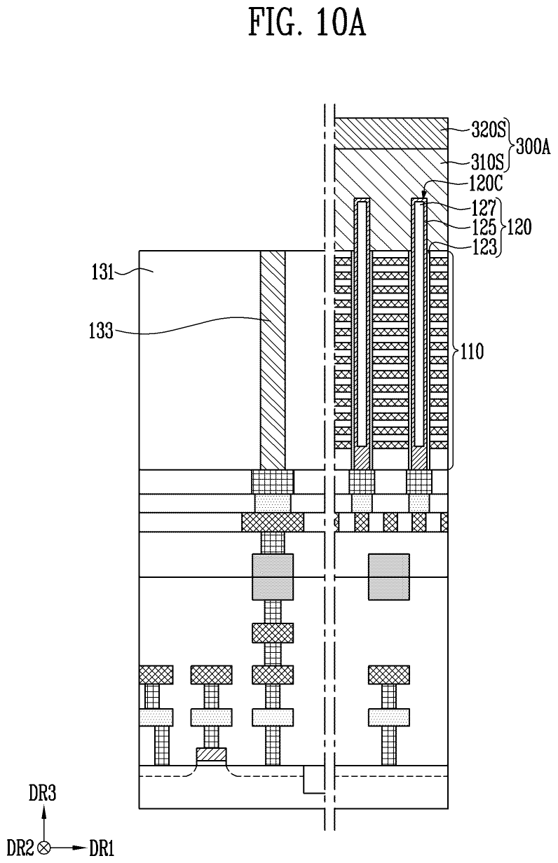

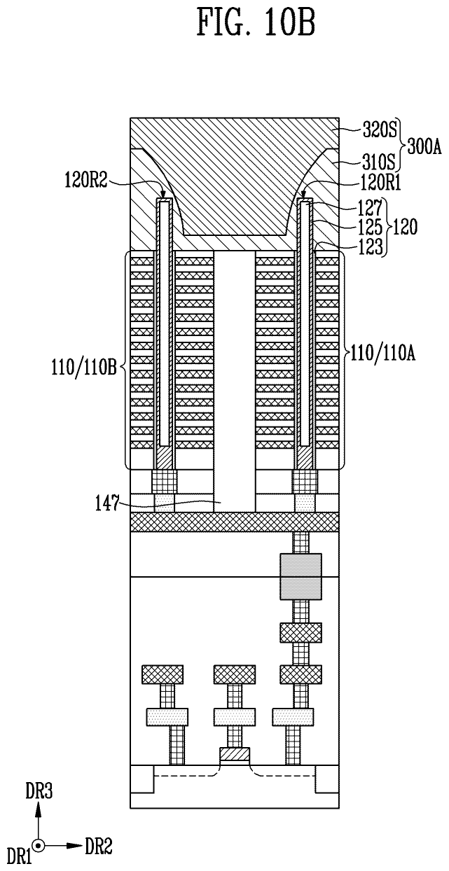

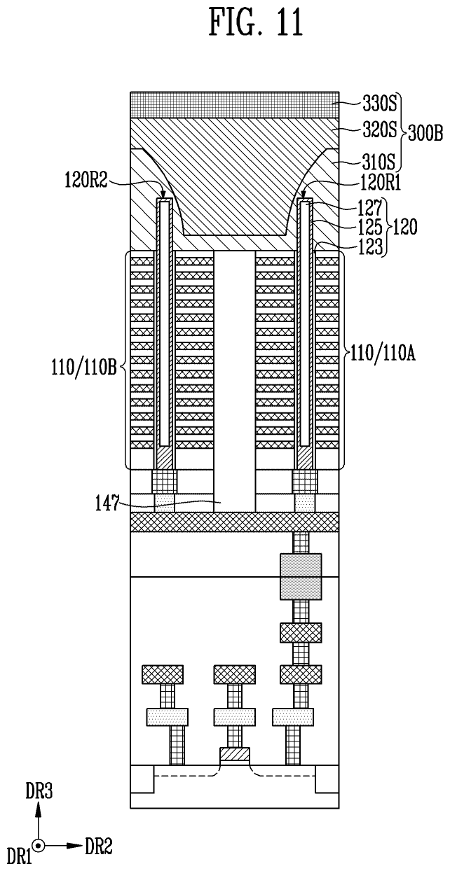

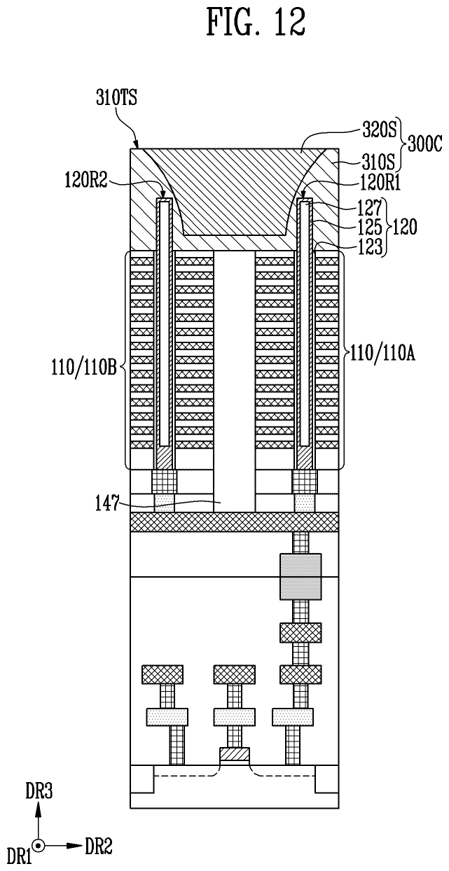

FIG. 7A, FIG. 8A, FIG. 9A, and FIG. 10A are sectional views illustrating a manufacturing method of a semiconductor memory device in accordance with an embodiment of the present disclosure, and each of FIG. 7A, FIG. 8A, FIG. 9A, and FIG. 10A illustrates a section of a structure for each unit process, taken along line I-I′ shown in FIG. 2A.

FIG. 7B, FIG. 8B, FIG. 9B, FIG. 10B, FIG. 11, FIG. 12, and FIG. 13 are sectional views illustrating a manufacturing method of a semiconductor memory device in accordance with an embodiment of the present disclosure, and each of FIG. 7B, FIG. 8B, FIG. 9B, FIG. 10B, FIG. 11, FIG. 12 and FIG. 13 illustrates a section of a structure for each unit process, taken along line II-II′ shown in FIG. 2A.

In the following drawings, the first direction DR1, the second direction DR2, and the third direction DR3 indicate directions facing axes intersecting one another. In an embodiment, the first direction DR1, the second direction DR2, and the third direction DR3 may be an X-axis direction, a Y-axis direction, and a Z-axis direction.

FIG. 5A and FIG. 5B illustrate a first structure 240 and a preliminary second structure 100, and illustrate a process of aligning the first structure 240 and the preliminary second structure 100.

Referring to FIG. 5A and FIG. 5B, as described with reference to FIG. 2A, FIG. 3A, and FIG. 3B, the first structure 240 includes a semiconductor substrate 211, an isolation layer 213, a first transistor 215A and a second transistor 215B of a peripheral circuit structure, interconnection structures 221, peripheral circuit-side bonding contacts 223, peripheral circuit-side bonding pads 225, and peripheral circuit-side insulating structures 211. The preliminary second structure 100 includes a sacrificial substrate 101, a first peripheral contact plug 133, a second peripheral contact plug 150B, a connection line 155CL, a gate structure 110, a plurality of pillar structures 120, a gate isolation structure 147, a plurality of bit line connection structures 150A, a plurality of bit lines 155BL, cell-side bonding contacts 163, and cell-side bonding pads 165.

The gate structure 110 of the preliminary second structure 100 is formed over one surface of the sacrificial substrate 101. As described with reference to FIG. 2A, FIG. 3A, and FIG. 3B, the gate structure 110 includes a first insulating layer 111A, conductive layers 113, second insulating layers 111B, and a third insulating layer 111C, each of which has a surface extending in the first direction DR1 and the second direction DR2. The conductive layers 113 and the second insulating layers 111B are alternately disposed in the third direction DR3 between the first insulating layer 111A and the third insulating layer 111C.

The preliminary second structure 100 includes a fourth insulating layer 131, a fifth insulating layer 141, a sixth insulating layer 143, a seventh insulating layer 145, and an eighth insulating layer 161, in addition to the first to third insulating layers 111A, 111B, and 111C of the gate structure 110. As described with reference to FIG. 3A and FIG. 3B, the fourth insulating layer 131 is disposed at the same level as the gate structure 110. The fourth insulating layer 131 is disposed over the one surface of the sacrificial substrate 101. As described with reference to FIG. 2A, FIG. 3A, and FIG. 3B, the fourth insulating layer 131 is penetrated by the first peripheral contact plug 133.

Each of the fifth insulating layer 141, the sixth insulating layer 143, the seventh insulating layer 145, and the eighth insulating layer 161 extends to cover the gate structure 110 and the fourth insulating layer 131. The fifth insulating layer 141 and the sixth insulating layer 143 is interposed between the seventh insulating layer 145 and each of the fourth insulating layer 131 and the gate structure 110. As described with reference to FIG. 2A, FIG. 3A, and FIG. 3B, the gate isolation structure 147 penetrates the conductive layers 113 and the first to third insulating layers 111A, 111B and 111C of the gate structure 110, and penetrates the fifth insulating layer 141 and the sixth insulating layer 143. The gate structure 110 is partitioned into gate stack structures (e.g., 110A and 110B) by the gate isolation structure 147.

The plurality of pillar structures 120 include center pillar structures 120C, a pillar structure 120R1 of a first row, and a pillar structure 120R2 of a second row. The pillar structure 120R1 of the first row correspond to the first pillar structure PS1 of the first row R1, which is shown in FIG. 2A, and the pillar structure 120R2 of the second row correspond to the first pillar structure PS1 of the second row R2, which is shown in FIG. 2A.

The plurality of pillar structures 120 penetrate the gate structure 110, and extend to the inside of the sacrificial substrate 101. Each pillar structure 120 includes a memory layer 123, a channel structure 125, and a core insulating layer 127. The memory layer 123 is disposed inside a channel hole. The channel hole penetrates the gate structure 110, and extends to the inside of the sacrificial substrate 101. The memory layer 123 is formed along a surface of the channel hole. The memory layer 123 includes a tunnel insulating layer, a data storage layer, and a blocking insulating layer as described with reference to FIG. 2B. The channel structure 125 includes a semiconductor layer formed along an inner wall of the memory layer 123. A central region of the channel hole, which is opened by the semiconductor layer of the channel structure 125, is filled with the core insulating layer 127 and a capping pattern. The capping pattern may constitute an end portion of the channel structure 125, which faces the bit line 155BL. The capping pattern may be formed of a doped semiconductor layer.

Each of the plurality of bit line connection structures 150A and the second peripheral contact plug 150B includes a first contact plug 151 and a second contact plug 153. A first contact plug 151 of each bit line connection structure 150A is connected to a channel structure 125 corresponding thereto, and a first contact plug 151 of the second peripheral contact plug 150B is connected to the first peripheral contact plug 133. As described with reference to FIG. 3A and FIG. 3B, the first contact plug 151 is formed of a conductive material penetrating the fifth insulating layer 141, and the second contact plug 153 is formed of a conductive material penetrating the sixth insulating layer 143.

Each bit line 115BL is connected to a second contact plug 153 of a bit line connection structure 150A corresponding thereto, and the connection line 155CL is connected to a second contact plug 153 of the second peripheral contact plug 150B. As described with reference to FIG. 3A and FIG. 3B, each of the plurality of bit lines 155BL and the connection line 155CL are formed of a conductive material penetrating the seventh insulating layer 145.

The cell-side bonding contacts 163 and the cell-side bonding pads 165 are disposed inside the eighth insulating layer 161. As described with reference to FIG. 3A and FIG. 3B, the cell-side bonding contacts 163 are connected to the connection line 155CL and the plurality of bit lines 155BL, and the cell-side bonding pads 165 include bonding surfaces exposed to the outside of the eighth insulating layer 161.

In an embodiment, a manufacturing process of the first structure 240 and a manufacturing process of a preliminary second structure 100 are individually performed. Accordingly, in an embodiment, damages of the first transistor 215A and the second transistor 215B according to various heat treatment processes performed in the manufacturing process of the preliminary second structure 100 may be prevented or reduced.

The first structure 240 and the preliminary second structure 100, which, in an embodiment, are provided through individual manufacturing processes, are aligned such that the peripheral circuit-side bonding pads 225 and the cell-side bonding pads 165 face each other.

Subsequently, the peripheral circuit-side bonding pads 225 and the cell-side bonding pads 165 are bonded to each other through a bonding process as shown in FIG. 6A and FIG. 6B.

Referring to FIG. 6A and FIG. 6B, the peripheral circuit-side bonding pads 225 and the cell-side bonding pads 165 are bonded to each other through a bonding process.

After the bonding process, the sacrificial substrate 101 shown in FIG. 5A and FIG. 5B is removed. The sacrificial substrate 101 may be removed by performing any one process or two or more processes among a grinding process, a planarization process, a dry etching process, and a wet etching process. Accordingly, each of the pillar structures 120 has a portion protruding to the outside of the gate structure 110.

Subsequently, a portion of the memory layer 123 is removed at the protruding portion of each of the pillar structures 120. Accordingly, the channel structure 125 of each of the pillar structures 120 is exposed.

After that, at least one of an n-type impurity and a p-type impurity may be implanted into an exposed portion of the channel structure 125. In an embodiment, a p-type impurity for counter doping and an n-type impurity for junction may be implanted into the exposed portion of the channel structure 125. The implantation of the impurity may be performed after the portion of the memory layer 123 is removed, or may be performed before the portion of the memory layer 123 is removed.

FIG. 7A, FIG. 7B, FIG. 8A, and FIG. 8B are sectional views illustrating a process of forming a first semiconductor layer.

Referring to FIG. 7A and FIG. 7B, a preliminary first semiconductor layer 310A is deposited to cover an exposed surface of the channel structure 125. The preliminary first semiconductor layer 310A fills a space between the pillar structure 120R1 of the first row and the pillar structure 120R2 of the second row, which are arranged at a distance wider than a distance between the center pillar structures 120C.

The preliminary first semiconductor layer 310A includes a conductivity type dopant as at least one of an n-type impurity and a p-type impurity. In an embodiment, the preliminary first semiconductor layer 310A may include, as a majority carrier, an n-type impurity such as phosphorus (P).

Referring to FIG. 8A and FIG. 8B, a heat treatment process on the preliminary first semiconductor layer 310A shown in FIG. 7A and FIG. 7B is performed such that the conductivity type dopant is activated. Accordingly, a first semiconductor layer 310B is formed. The heat treatment process includes a laser annealing process and the like. Due to influence of the heat treatment process, surface roughness of the first semiconductor layer 310B is increased as compared with surface roughness of the preliminary semiconductor layer 310A shown in FIG. 7A and FIG. 7B. In addition, a top recessed portion 310TRP is formed at a surface of the first semiconductor layer 310B. The top recessed portion 310TRP is disposed between the pillar structure 120R1 of the first row and the pillar structure 120R2 of the second row, which are arranged at the distance wider than the distance between the center pillar structures 120C. Accordingly, a thickness of the first semiconductor layer 310B in the third direction DR3 is small in a region between the pillar structure 120R1 of the first row and the pillar structure 120R2 of the second row as compared with a region between the center pillar structures 120C.

FIG. 9A and FIG. 9B are sectional views illustrating a process of forming a second semiconductor layer.

Referring to FIG. 9A and FIG. 9B, a preliminary second semiconductor layer is deposited to fill the top recessed portion 310TRP of the first semiconductor layer 310B. The preliminary second semiconductor layer is deposited over the first semiconductor layer 310B in a state in which the surface of the first semiconductor layer 310B is not planarized.

The preliminary second semiconductor layer includes a conductivity type dopant as at least one of an n-type impurity and a p-type impurity. In an embodiment, the preliminary second semiconductor layer may include the n-type impurity as a majority carrier.

Subsequently, a heat treatment process on the preliminary second semiconductor layer is performed such that the conductivity type dopant in the preliminary second semiconductor layer is activated. The heat treatment process includes a laser annealing process and the like. After that, a heat-treated surface of the preliminary second semiconductor layer is planarized, thereby forming a second semiconductor layer 320. In an embodiment, because the planarization of the preliminary second semiconductor layer is performed in a state in which the pillar structures 120 are protected by the first semiconductor layer 310B, a damage of the channel structure 125 of each of the pillar structures 120 by a planarization process may be reduced or prevented.

The second semiconductor layer 320 remains to fill the top recessed portion 310TRP of the first semiconductor layer 310B. The second semiconductor layer 320 covers the first semiconductor layer 310B, and overlaps with the center pillar structures 120, the pillar structure 120R1 of the first row, and the pillar structure 120R2 of the second row. A concentration of a conductivity type dopant or a majority carrier is high in the second semiconductor layer 320 as compared with the first semiconductor layer 310B.

FIG. 10A and FIG. 10B are sectional views illustrating a process of forming a source structure in accordance with an embodiment of the present disclosure.

Referring to FIG. 10A and FIG. 10B, a portion of each of the first semiconductor layer and the second semiconductor layer, which overlap with the first peripheral contact plug 133 and the fourth insulating layer 131, is removed. A remaining first semiconductor layer and a remaining second semiconductor layer constitute a doped semiconductor structure. The first semiconductor layer constituting a first doped region of the doped semiconductor structure is indicated by “310S,” and the second semiconductor layer constituting a second doped region of the doped semiconductor structure is indicated by “320S.” The first semiconductor layer 310S and the second semiconductor layer 320S constitute a source structure 300A.

FIG. 11 is a sectional view illustrating processes of forming a source structure in accordance with an embodiment of the present disclosure.

Referring to FIG. 11, a metal layer is formed over the second semiconductor layer 320 shown in FIG. 9A and FIG. 9B. Subsequently, a portion of each of the first semiconductor layer, the second semiconductor layer, and the metal layer, which overlap with the first peripheral contact plug 133 and the fourth insulating layer 131, which are shown in FIG. 9A and FIG. 9B, is removed. A remaining first semiconductor layer, a remaining second semiconductor layer, and a remaining metal layer constitute a source structure 300B. The first semiconductor layer remaining to constitute a first doped region of the source structure 300B is indicated by “310S,” the second semiconductor layer remaining to constitute a second doped region of the source structure 300B is indicated by “320S,” and the metal layer remaining to constitute the source structure 300B is indicated by “330S.”

FIG. 12 is a sectional view illustrating process of forming a source structure in accordance with an embodiment of the present disclosure.

Referring to FIG. 12, the second semiconductor layer 320 shown in FIG. 9A and FIG. 9B is planarized such that a top surface 310TS of the first semiconductor layer is exposed. Subsequently, a portion of each of the first semiconductor layer and the second semiconductor layer, which overlap with the first peripheral contact plug 133 and the fourth insulating layer 131, which are shown in FIG. 9A and FIG. 9B, is removed. A remaining first semiconductor layer and a remaining second semiconductor layer constitute a source structure 300C. The first semiconductor layer remaining to constitute a first doped region of the source structure 300C is indicated by “310S,” and the second semiconductor layer remaining to constitute a second doped region of the source structure 300C is indicated by “320S.”

FIG. 13 is a sectional view illustrating process of forming a source structure in accordance with an embodiment of the present disclosure.

Referring to FIG. 13, the second semiconductor layer 320 shown in FIG. 9A and FIG. 9B is planarized such that a top surface 310TS of the first semiconductor layer is exposed or opened at both sides of the second doped region 320S. Subsequently, a metal layer is formed over the planarized second semiconductor layer. After that, a portion of each of the first semiconductor layer, the second semiconductor layer, and the metal layer, which overlap with the first peripheral contact plug 133 and the fourth insulating layer 131, which are shown in FIG. 9A and FIG. 9B, is removed. A remaining first semiconductor layer, a remaining second semiconductor layer, and a remaining metal layer constitute a source structure 300D. The first semiconductor layer remaining to constitute a first doped region of the source structure 300D is indicated by “310S,” the second semiconductor layer remaining to constitute a second doped region of the source structure 300D is indicated by “320S,” and the metal layer remaining to constitute the source structure 300D is indicated by “330S.”

After the source structure 300A shown in FIG. 10A and FIG. 10B, the source structure 300B shown in FIG. 11, the source structure 300C shown in FIG. 12, or the source structure 300D shown in FIG. 13 is formed, subsequent processes may be performed, such as a process of forming an upper insulating layer, a process of forming a source contact plug and a third peripheral contact plug, and a process of forming an upper conductive pattern such as a common source layer.

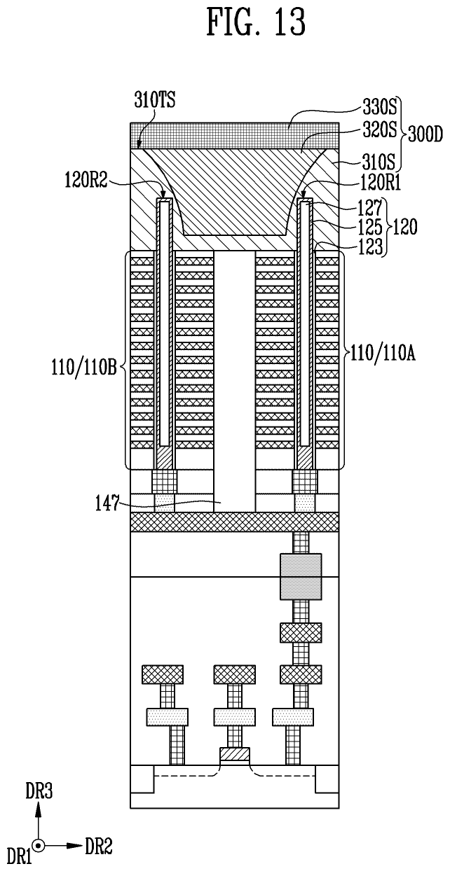

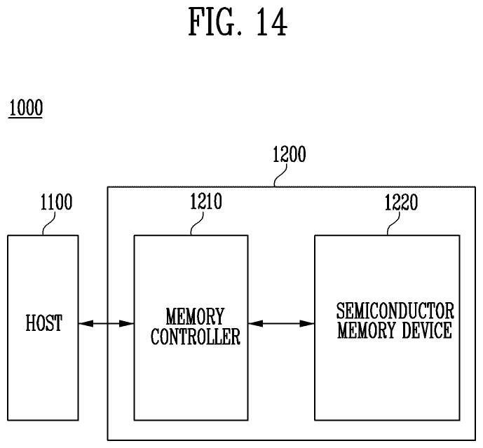

FIG. 14 is a block diagram illustrating an electronic system in accordance with an embodiment of the present disclosure.

Referring to FIG. 14, the electronic system 1000 may be a computing system, a medical device, a communication device, a wearable device, a memory system, or the like. The electronic system 1000 may include a host 1100 and a storage device 1200.

The host 1100 may store data in the storage device 1200 or read data stored in the storage device 1200, based on an interface. The interface may include at least one of a Double Data Rate (DDR) interface, a Universal Serial Bus (USB) interface, a Multi-Media Card (MMC) interface, an embedded MMC (eMMC) interface, a Peripheral Component Interconnection (PCI) interface, a PCI-Express (PCI-E) interface, an Advanced Technology Attachment (ATA) interface, a Serial ATA (SATA) interface, a Parallel ATA (PATA) interface, a Small Computer System Interface (SCSI), an Enhanced Small Disk Interface (ESDI), an Integrated Drive Electronics (IDE) interface, a firewire interface, a Universal Flash Storage (UFS) interface, and a Non-Volatile Memory express (NVMe) interface.

The storage device 1200 may include a memory controller 1210 and a semiconductor memory device 1220. In an embodiment, the storage device 1200 may be a storage medium such as a Solid State Drive (SSD) or a Universal Serial Bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a nonvolatile memory device. The semiconductor memory device 1220 may include a pillar structure of a first row and a pillar structure of a second row, which penetrate a gate structure, extend to the inside of a source structure, and are adjacent to each other. The source structure may include a first semiconductor layer and a second semiconductor layer, which are stacked between the pillar structure of the first row and the pillar structure of the second row, or include a first doped region and a second doped region, which have different concentrations of a conductivity type dopant between the pillar structure of the first row and the pillar structure of the second row.

In accordance with various embodiments of the present disclosure, a thickness of a semiconductor layer or a doped region of a source structure may be secured between a pillar structure of a first row and a pillar structure of a second row, which are adjacent to each other. Accordingly, in an embodiment, the operation reliability of the semiconductor memory device may be improved.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor memory device comprising:
a gate structure including a surface extending in a first direction and a second direction, the first direction different from the second direction, the gate structure including insulating layers and conductive layers, the insulating layers and the conductive layers alternately disposed in a stacking direction protruding from the surface;
a source structure overlapping with the gate structure; and
a plurality of pillar structures penetrating the insulating layers and the conductive layers, the plurality of pillar structures extending to the inside of the source structure,
wherein each of the plurality of pillar structures includes:
a channel structure penetrating the insulating layers and the conductive layers, the channel structure extending to the inside of the source structure; and
a memory layer between the channel structure and the gate structure, and
wherein the source structure incudes:
a first semiconductor layer including a bottom recessed portion into which the channel structure is inserted and a top recessed portion disposed between a pillar structure of a first row and a pillar structure of a second row, which are adjacent to each other, among the plurality of pillar structure; and
a second semiconductor layer disposed over the first semiconductor layer to fill the top recessed portion.

2. The semiconductor memory device of claim 1, further comprising a gate isolation structure disposed between the pillar structure of the first row and the pillar structure of the second row, the gate isolation structure penetrating the insulating layers and the conductive layers,
wherein the top recessed portion of the first semiconductor layer overlaps with the gate isolation structure.

3. The semiconductor memory device of claim 2, wherein the plurality of pillar structures further include center pillar structures arranged to be spaced apart from the gate isolation structure at a distance greater than a distance at which the pillar structure of the first row and the pillar structure of the second row are spaced apart from the gate isolation structure, and
wherein a distance between the pillar structure of the first row and the pillar structure of the second row is greater than a distance between the center pillar structures.

4. The semiconductor memory device of claim 1, wherein a width of the top recessed portion is wider than a width of the bottom recessed portion.

5. The semiconductor memory device of claim 1, wherein the first semiconductor layer includes a top surface higher than a bottom of the top recessed portion, and
wherein the second semiconductor layer extends to cover the top surface of the first semiconductor layer.

6. The semiconductor memory device of claim 5, wherein the source structure further includes a metal layer over the second semiconductor layer, and
wherein each of the first semiconductor layer and the second semiconductor layer extends between the gate structure and the metal layer.

7. The semiconductor memory device of claim 1, wherein the first semiconductor layer includes a top surface higher than a bottom of the top recessed portion, and
wherein the second semiconductor layer does not overlap with the top surface of the first semiconductor layer.

8. The semiconductor memory device of claim 7, wherein the source structure further includes a metal layer over the second semiconductor layer, and
wherein the metal layer extends to overlap with the top surface of the first semiconductor layer.

9. The semiconductor memory device of claim 1, wherein each of the first semiconductor layer and the second semiconductor layer includes a conductivity type dopant,
wherein a concentration of the conductivity type dopant is higher in the second semiconductor layer than the first semiconductor layer,
wherein the conductivity type dopant is n-type dopant or p-type dopant.

10. A semiconductor memory device comprising:
a gate structure including a surface extending in a first direction and a second direction, the first direction different from the second direction, the gate structure including insulating layers and conductive layers, the insulating layers and the conductive layers alternately disposed in a stacking direction protruding from the surface;
a doped semiconductor structure overlapping with the gate structure, the doped semiconductor structure including a conductivity type dopant; and
a plurality of pillar structures penetrating the insulating layers and the conductive layers, the plurality of pillar structures extending to the inside of the doped semiconductor structure,
wherein each of the plurality of pillar structures includes:
a channel structure penetrating the insulating layers and the conductive layers, the channel structure extending to the inside of the doped semiconductor structure; and
a memory layer between the channel structure and the gate structure,
wherein the doped semiconductor structure includes:
a first doped region in contact with the channel structure, the first doped region including the conductivity type dopant at a first concentration; and
a second doped region disposed over the first doped region, the second doped region including the conductivity type dopant at a second concentration different from the first concentration, and
wherein a first thickness of the first doped region in the stacking direction and a second thickness of the second doped region in the stacking direction vary between a pillar structure of a first row and a pillar structure of a second row, which are adjacent to each other, among the plurality of pillar structures.

11. The semiconductor memory device of claim 10, wherein the second concentration is higher than the first concentration.

12. The semiconductor memory device of claim 10, wherein a sum of the first thickness and the second thickness is substantially constant between the pillar structure of the first row and the pillar structure of the second row.

13. The semiconductor memory device of claim 10, further comprising a gate isolation structure disposed between the pillar structure of the first row and the pillar structure of the second row, the gate isolation structure penetrating the insulating layers and the conductive layers,
wherein the first thickness decreases as the first thickness is measured closer to the gate isolation structure, and
the second thickness increases as the second thickness is measured closer to the gate isolation structure.

14. The semiconductor memory device of claim 13, wherein the plurality of pillar structures further include center pillar structures arranged to be spaced apart from the gate isolation structure at a distance greater than a distance at which the pillar structure of the first row and the pillar structure of the second row are spaced apart from the gate isolation structure, and
wherein a distance between the pillar structure of the first row and the pillar structure of the second row is greater than a distance between the center pillar structures.

15. The semiconductor memory device of claim 14,
wherein the first doped region extends to overlap with the center pillar structures, and
wherein the first thickness of the first doped region is greater on the top of each of the center pillar structures than on the top of each of the pillar structure of the first row and the pillar structure of the second row.

16. The semiconductor memory device of claim 14,
wherein the second doped region extends to overlap with the center pillar structures, and
wherein the second thickness of the second doped region is smaller on the top of each of the center pillar structures than on the top of each of the pillar structure of the first row and the pillar structure of the second row.

17. The semiconductor memory device of claim 14, wherein the second doped region does not overlap with the center pillar structures.

18. The semiconductor memory device of claim 10, further comprising a metal layer connected to the second doped region,
wherein each of the first doped region and the second doped region extends between the gate structure and the metal layer.

19. The semiconductor memory device of claim 10, further comprising a metal layer connected to the second doped region,
wherein the first doped region includes a top surface opened at both sides of the second doped region, and
wherein the metal layer extends to overlap with the top surface of the first doped region.
